(19) United States
(12) Patent Application Publication
(10) Pub. No.: US 2017/0012145 A1
(43) Pub. Date: Jan. 12, 2017

(54) METHOD FOR ROUGHENING SILICON SUBSTRATE SURFACE

(71) Applicant: NATIONAL PINGTUNG UNIVERSITY OF SCIENCE & TECHNOLOGY, Pingtung County (TW)

(72) Inventor: Wei-Hua Lu, Pingtung County (TW)

(21) Appl. No.: 15/175,196

(22) Filed: Jun. 7, 2016

(30) Foreign Application Priority Data
Jul. 10, 2015 (TW) 104122455

(51) Int. Cl. H01L 31/0236; H01L 31/028

(52) U.S. Cl. CPC H01L 31/02366; H01L 31/028

(57) ABSTRACT

A method for roughening silicon substrate surface includes providing a silicon substrate having a waiting-for-etching surface, the waiting-for-etching surface has a plurality of first and second areas; forming a plurality of covering bumps on the first areas, and a gap is formed between each of the covering bumps and each of the first areas; and etching the waiting-for-etching solution by a anisotropic etching solution. The anisotropic etching solution permeates into each of the first areas through the gap to lead the etching time of the first areas is shorter than that of the second areas, so the waiting-for-etching surface becomes a undulate surface having a plurality of undulate structures because the etching depth of the first areas is smaller than that of the second areas.

### FIELD OF THE INVENTION

The present invention relates to a method for roughening silicon substrate surface, particularly relates to a method for roughening silicon substrate surface by etching depth difference.

### BACKGROUND OF THE INVENTION

Photovoltaic conversion efficiency of conventional solar cell is low because most light will reflect and can not be absorbed by the conventional silicon substrate which is cut by diamond wire and displays inadequate surface roughness. Therefore, increase the surface roughness of the silicon substrate to improve light intensity is essential for requirement of solar cell.

### SUMMARY

The present invention uses a plurality of covering bump formed on a silicon substrate surface to form undulate structure on the silicon substrate surface for increasing surface roughness of the silicon substrate, wherein the undulate structure is formed because of different etching time and different etching depth between the silicon substrate surface under the covering bumps and the silicon substrate surface without covering of the covering bumps.

A method for roughening silicon substrate surface includes providing a silicon substrate having a waiting-for-etching surface and a bottom surface, wherein the waiting-for-etching surface has a plurality of first areas and a plurality of second areas, and each of the first areas is adjacent to each of the second areas; forming a plurality of covering bumps on the first areas, a gap is formed between each of the covering bumps and each of the first areas, and a space is formed between each adjacent pair of the covering bumps, wherein the gap comprises at least one opening communicating with the space, and the space reveals the second areas; performing a etching treatment, the waiting-for-etching surface of the silicon substrate is anisotropic etched by a anisotropic etching solution, the anisotropic etching solution is filled in the space and contacts with each of the second areas for etching each of the second areas, and the anisotropic etching solution permeates into the gap formed between each of the covering bumps and each of the first areas through the opening to etch each of the first areas under each of the covering bumps, the anisotropic etching solution contacts with each of the second areas and then contracts with each of the first areas through the gap to form a time difference between anisotropic etching time of the first areas and the second areas to make each of the first areas and each of the second areas forms irregular and undulate surface respectively, and the etching depth of the first areas is lower than the etching depth of the second areas to make the waiting-for-etching surface becomes a undulate surface, wherein the undulate surface comprises a plurality of irregular undulate structures, and each of the undulate structures has a peak formed on the first area, a valley formed on the second area and a connection portion formed between the peak and the valley, a first height is defined between the peak and the bottom surface, a second height is defined between the valley and the bottom surface, and a third height is defined between the connection portion and the bottom surface, wherein the first height is higher than the second height, the third height is between the first height and the second height, and the third height is increased gradually from the valley to the peak, and wherein each of the valley of the undulate surface communicates with each other; removing the anisotropic etching solution; and removing each of the covering bumps.

Etching depth difference between the first and second areas of the waiting-for-etching surface because of blocking by the covering bumps and solution guiding by the gap leads the waiting-for-etching surface form the undulate surface. Each of the undulate structures of the undulate surface is able to increase surface roughness of the undulate surface to decrease light reflectivity, improve light intensity and photovoltaic conversion efficiency of the silicon substrate.

### DESCRIPTION OF THE DRAWINGS

FIG. 1 is a flow chart illustrating a method for roughening silicon substrate surface in accordance with a first embodiment of the present invention.

FIGS. 2 to 7 are diagrams illustrating the method for roughening silicon substrate surface in accordance with the first embodiment of the present invention.

FIGS. 8 and 9 are diagrams illustrating a method for forming covering bumps in accordance with a second embodiment of the present invention.

FIG. 10 is a SEM image of a silicon substrate before surface roughening.

FIG. 11 is a SEM image of a silicon substrate after surface roughening.

FIG. 12 is an AFM image of a silicon substrate before surface roughening.

FIG. 13 is an AFM image of a silicon substrate after surface roughening.

### DETAILED DESCRIPTION OF THE INVENTION

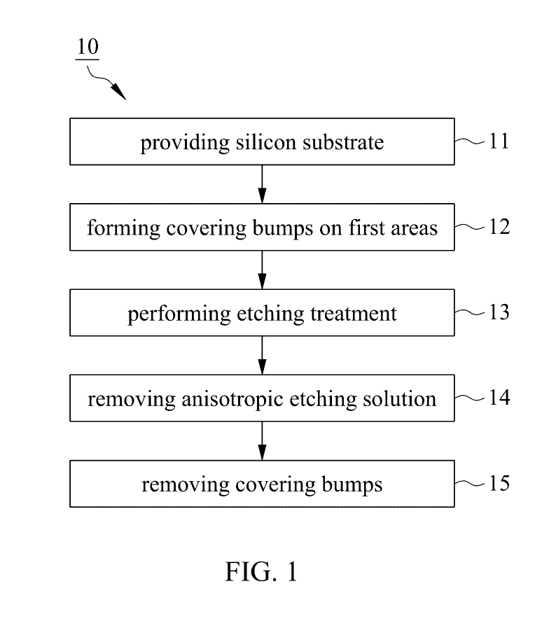

With reference to FIG. 1, a method for roughening silicon substrate surface 10 in accordance with a first embodiment of the present invention includes step 11 of providing silicon substrate, step 12 of forming covering bumps on first areas, step 13 of performing etching treatment, step 14 of removing anisotropic etching solution and step 15 of removing covering bumps.

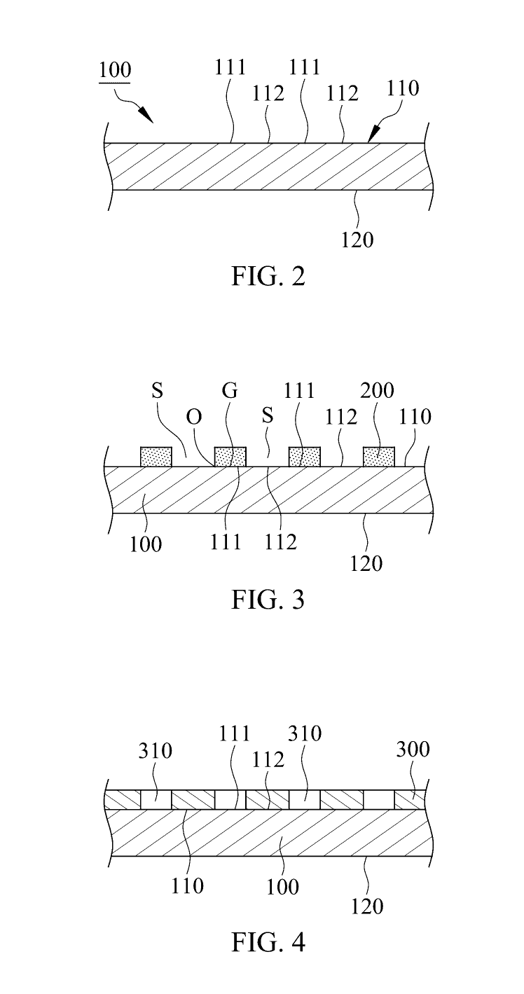

With reference to FIGS. 1 and 2, in the step 11 of providing a silicon substrate 100, the silicon substrate 100 is selectable from single or poly crystal silicon substrate, and the silicon substrate 100 is poly crystal silicon substrate in this embodiment. The silicon substrate 100 has a waiting-for-etching surface 110 and a bottom surface 120, wherein the waiting-for-etching surface 110 has a plurality of first areas 111 and a plurality of second areas 112, and each of the first areas 111 is adjacent to each of the second areas 112.

With reference to FIGS. 1 and 3, in the step 12 of forming a plurality of covering bumps 200 on the first areas 111 of the waiting-for-etching surface 110, a space S is formed between each adjacent pair of the covering bumps 200 and reveals the second areas 112. A gap G is formed between each of the covering bumps 200 and each of the first areas 111, wherein the gap G has at least one opening O communicating with the space S. In this embodiment, width of each of the covering bumps 200 is between 5 and 300 μm.

With reference to FIGS. 4 to 6, a method for forming the covering bumps 200 in a first embodiment of the present invention is providing a screen plate 300 firstly, wherein the screen plate 300 is made of anti-corrosive material, and comprises a plurality of meshes 310. With reference to FIG. 4, the screen plate 300 is deposited on the waiting-for-etching surface 110 of the silicon substrate 100, and each of the meshes 310 reveals each of the first areas 111 of the waiting-for-etching surface 110. With reference to FIGS. 5 and 6, a scraper K is used to fill a covering layer 400 in each of the meshes 310 to make the covering layer 400 covering each of the first areas 111. In this embodiment, the covering layer 400 is epoxy. Then, a solidification treatment is performed to solidify the covering layer 400 for forming the covering bumps 200. The covering layer 400 is solidified at 80 to 300 degrees Celsius in the solidification treatment preferably, and the covering layer 400 is solidified at 180 degrees Celsius in this embodiment. After the solidification treatment, the screen plate 300 is removed for revealing each of the second areas 112 (please referring FIG. 3).

With reference to FIGS. 1, 3 and 7, in the step 13 of performing an etching treatment, the waiting-for-etching surface 110 of the silicon substrate 100 is anisotropic etched by an anisotropic etching solution. The anisotropic etching solution is 10 to 40% KOH preferably, and 30% KOH is used for etching the waiting-for etching surface 110 by ultrasonication in this embodiment. In the etching treatment, the anisotropic etching solution is filled in the space S between each adjacent pair of the covering bumps 200 and contacts with each of the second areas 112 to perform anisotropic etching. And the anisotropic etching solution permeates slowly into the gap G between each of the covering bumps 200 and each of the first areas 111 through the opening O communicated with the space S to contact with the first areas 111 and perform anisotropic etching. The anisotropic etching solution contacts with each of the second areas 112 firstly, and then contracts with each of the first areas 111 through the gap G, a time difference is formed between anisotropic etching time of the first areas 111 and the second areas 112 to make each of the first areas 111 and each of the second areas 112 forming irregular and undulate surface respectively, and make the etching depth of the first areas 111 is smaller than the etching depth of the second areas 112, so the waiting-for-etching surface 110 becomes a undulate surface 130.

With reference to FIG. 7, the undulate surface 130 comprises a plurality of irregular undulate structures 131, wherein each of the undulate structures 131 has a peak 131a, a valley 131b and a connection portion 131c. The peak 131a is formed on each of the first areas 111 covered by each of the covering bumps 200, the valley 131b is formed on each of the second areas 112 contacting with the anisotropic etching solution directly, and the connection portion 131c is formed between the peak 131a and the valley 131b. A first height H1 is defined between the peak 131a and the bottom surface 120 of the silicon substrate 100, a second height H2 is defined between the valley 131b and the bottom surface 120 of the silicon substrate 100, and a third height H3 is defined between the connection portion 131c and the bottom surface 120 of the silicon substrate 100. Owing to the etching depth of each of the first areas 111 is lower than the etching depth of each of the second areas 112, the first height H1 is higher than the second height H2, and the third height H3 is between the first height H1 and the second height H2. In addition, the anisotropic etching solution permeates gradually into each of the first areas 111 from outside to inside to make the time which the anisotropic etching solution contacts with each of the first areas 111 decreasing gradually from outside to inside, so the third height H3 is increased gradually from the valley 131b to the peak 131a.

With reference to FIG. 1, the step 14 is removing the anisotropic etching solution to stop the etching treatment, and the step 15 is removing each of the covering bumps 200. Each of the covering bumps 200 is removed by burning or etching, wherein burning means the covering bumps 200 are removed at 400 to 1000 degrees Celsius, preferably, the covering bumps 200 are removed at 800 degrees Celsius, and etching means the covering bumps 200 are removed by an etching solution which can not corrode the silicon substrate 100, and wherein the etching solution is selected from acidic or alkaline etching solution.

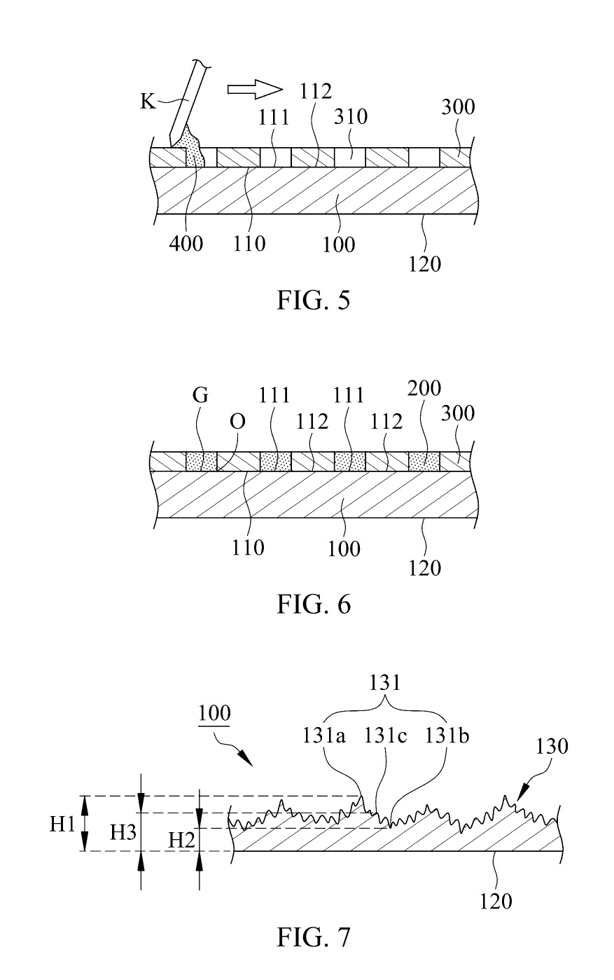

With reference to FIG. 8, a method for forming the covering bumps 200 in a second embodiment of the present invention is coating the covering layer 400 on the waiting-for-etching surface 110 of the silicon substrate 100, and then performing the solidification treatment to solidify the covering layer 400 at 80 to 300 degrees Celsius. In this embodiment, the covering layer 400 is solidified at 180 degrees Celsius. With reference to FIG. 9, a removing procedure is performed to remove the solidified covering layer 400 on each of the second areas 112 for revealing each of the second areas 112, and the solidified covering layer 400 on each of the first areas 111 becomes each of the covering bumps 200. In this embodiment, the covering layer 400 on each of the second areas 112 is removed by laser in the removing procedure, wherein the laser is UV laser preferably.

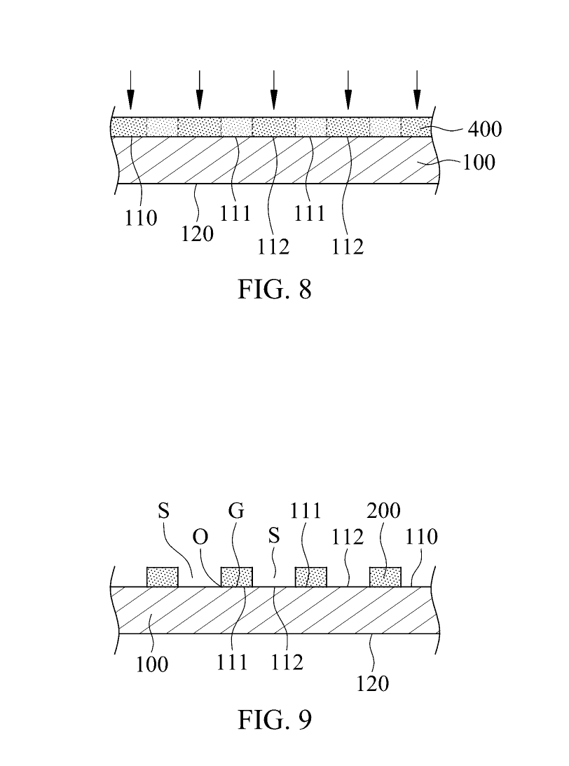

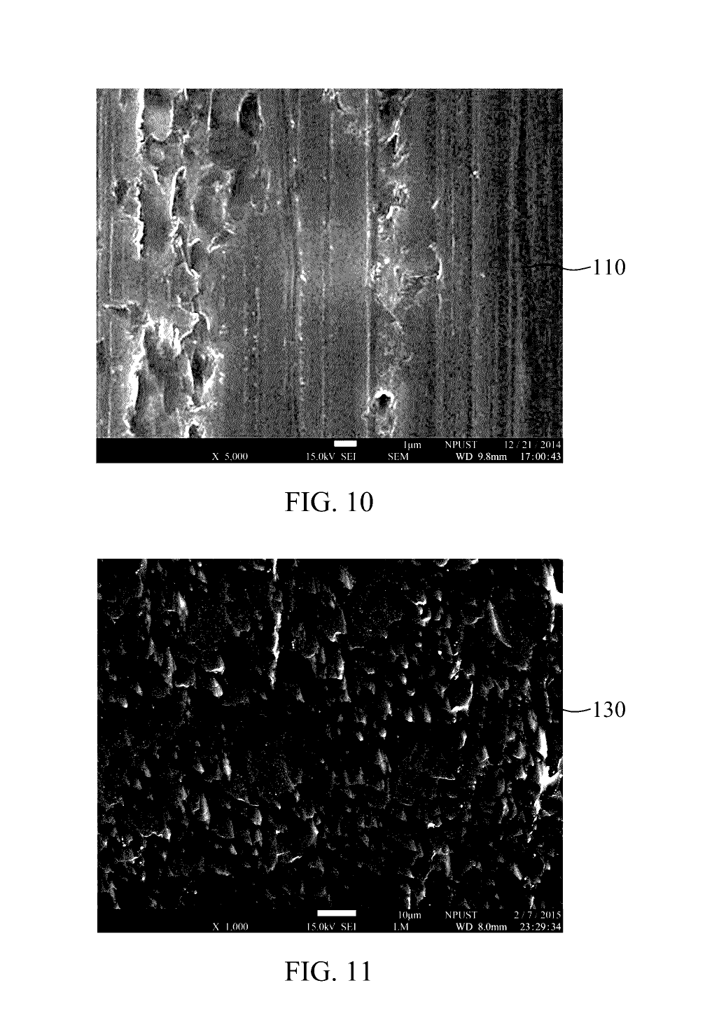

With reference to FIG. 10, it is a SEM (Scanning Electron Microscope) image of the waiting-for-etching surface 110 of the silicon substrate 100 before surface roughening. With reference to FIG. 11, it is a SEM (Scanning Electron Microscope) image of the undulate surface 130 formed after surface roughening. After comparing FIG. 10 to FIG. 11, it is clear to know the method for roughening silicon substrate surface 10 of the present invention is able to etch the waiting-for-etching surface 110 to become the undulate surface 130 for increasing the surface roughness of the silicon substrate 100.

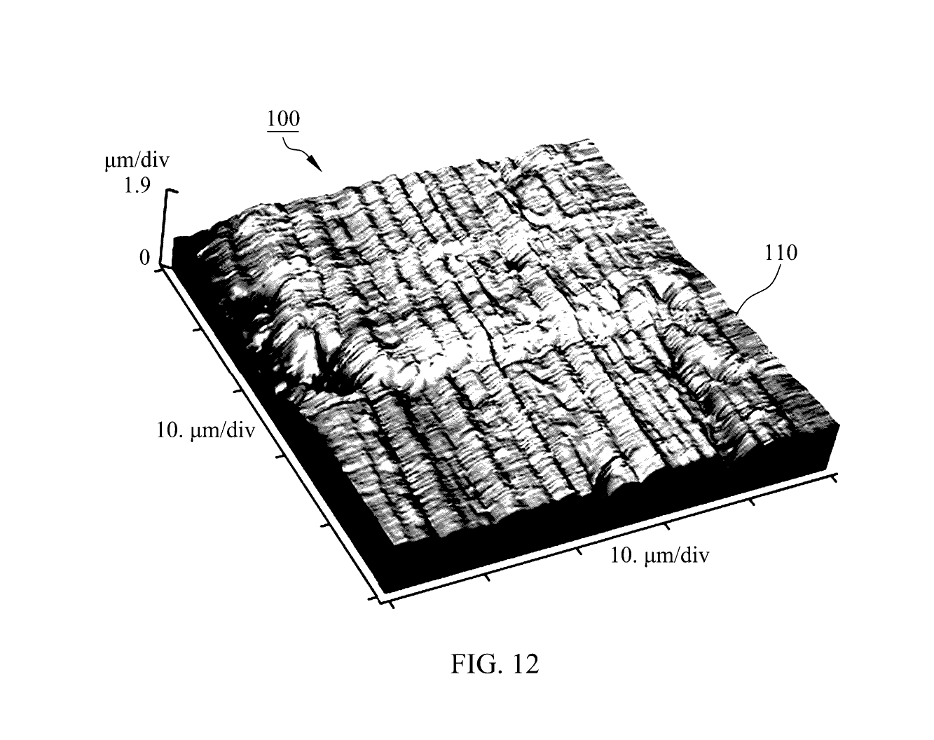

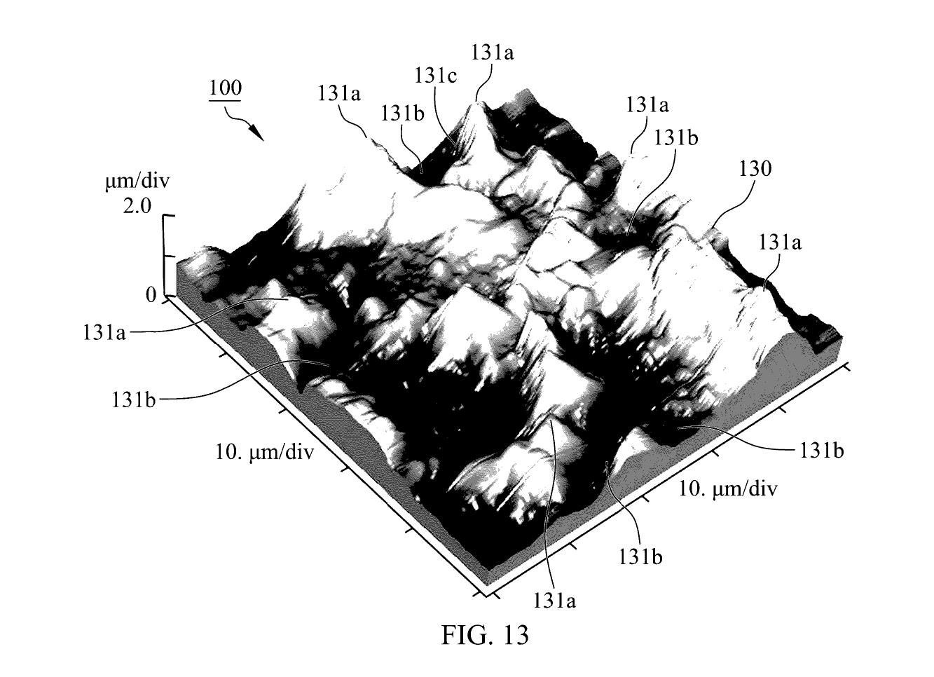

With reference to FIG. 12, it is an AFM (Atomic Force Microscope) image of the silicon substrate 100 before surface roughening. The waiting-for-etching surface 110 of the silicon substrate 100 displays small height undulation, so the surface roughness of the waiting-for-etching surface 110 of the silicon substrate 100 is inadequate to decrease light reflectivity and increase light intensity. In this embodiment, the arithmetic average roughness (Ra) of the waiting-for-etching surface 110 of the silicon substrate 100 is 0.1001 μm, the root mean square roughness (RMS/Rq) is 0.1534 μm, and the maximum height roughness (Rmax) is 1.9199 μm. With reference to FIG. 13, it is an AFM (Atomic Force Microscope) image of the silicon substrate 100 after surface roughening. The waiting-for-etching surface 110 becomes the undulate surface 130 with different etching depth after surface roughening, and each of the valleys 131b of the undulate surface 130 communicates with each other. The surface roughness of the undulate surface 130 is higher than the waiting-for-etching surface 110 to decrease light reflectivity and increase light intensity, and then improve the photovoltaic conversion efficiency of the silicon substrate 100. In this embodiment, the arithmetic average roughness (Ra) of the undulate surface 130 of the silicon substrate 100 is 0.5263 μm, the root mean square roughness (RMS/Rq) is 0.6663 μm, and the maximum height roughness (Rmax) is 4.0228 μm.

While this invention has been particularly illustrated and described in detail with respect to the preferred embodiments thereof, it will be clearly understood by those skilled in the art that is not limited to the specific features shown and described and various modified and changed in form and details may be made without departing from the spirit and scope of this invention.

What is claimed is:

1. A method for roughening silicon substrate surface including:
providing a silicon substrate having a waiting-for-etching surface and a bottom surface, wherein the waiting-for-etching surface has a plurality of first areas and a plurality of second areas, and each of the first areas is adjacent to each of the second areas;
forming a plurality of covering bumps on the first areas, a gap is formed between each of the covering bumps and each of the first areas, and a space is formed between each adjacent pair of the covering bumps, wherein the space reveals the second areas, and the gap comprises at least one opening communicating with the space;
performing a etching treatment, the waiting-for-etching surface of the silicon substrate is anisotropic etched by a anisotropic etching solution, the anisotropic etching solution is filled in the space and contacts with each of the second areas for etching each of the second areas, and the anisotropic etching solution permeates into the gap formed between each of the covering bumps and each of the first areas through the opening to etch each of the first areas under each of the covering bumps, the anisotropic etching solution contacts with each of the second areas and then contracts with each of the first areas through the gap to form a time difference between anisotropic etching time of the first areas and the second areas to make each of the first areas and each of the second areas forms irregular and undulate surface respectively, and the etching depth of the first areas is lower than the etching depth of the second areas to make the waiting-for-etching surface becomes a undulate surface, wherein the undulate surface comprises a plurality of irregular undulate structures, and each of the undulate structures has a peak formed on the first area, a valley formed on the second area and a connection portion formed between the peak and the valley, a first height is defined between the peak and the bottom surface, a second height is defined between the valley and the bottom surface, and a third height is defined between the connection portion and the bottom surface, wherein the first height is higher than the second height, the third height is between the first height and the second height, and the third height is increased gradually from the valley to the peak, and wherein each of the valley of the undulate surface communicates with each other;
removing the anisotropic etching solution; and
removing each of the covering bumps.

2. The method for roughening silicon substrate surface in accordance with claim 1, wherein a method for forming the covering bumps including:
providing a screen plate, the screen plate is deposited on the waiting-for-etching surface of the silicon substrate, wherein the screen plate comprising a plurality of meshes, and each of the meshes reveals each of the first areas;
filling a covering layer in each of the meshes, wherein the covering layer covers each of the first areas;
performing a solidification treatment to solidify the covering layer for forming each of the covering bumps; and
removing the screen plate.

3. The method for roughening silicon substrate surface in accordance with claim 1, wherein a method for forming the covering bumps including:
coating a covering layer on the waiting-for-etching surface of the silicon substrate;
performing a solidification treatment to solidify the covering layer; and
performing a removing procedure to remove the covering layer on each of the second areas for revealing each of the second areas, wherein the covering layer on each of the first areas becomes each of the covering bumps.

4. The method for roughening silicon substrate surface in accordance with claim 3, wherein the covering layer on each of the second areas is removed by laser in the removing procedure.

5. The method for roughening silicon substrate surface in accordance with claim 2, wherein the covering layer is solidified at 80 to 300 degrees Celsius in the solidification treatment.

6. The method for roughening silicon substrate surface in accordance with claim 3, wherein the covering layer is solidified at 80 to 300 degrees Celsius in the solidification treatment.

7. The method for roughening silicon substrate surface in accordance with claim 1, wherein the anisotropic etching solution is 10 to 40% KOH.

8. The method for roughening silicon substrate surface in accordance with claim 1, wherein each of the covering bumps is removed by burning.

9. The method for roughening silicon substrate surface in accordance with claim 8, wherein each of the covering bumps is removed at 400 to 1000 degrees Celsius.

10. The method for roughening silicon substrate surface in accordance with claim 1, wherein each of the covering bumps is removed by etching which uses an etching solution to remove each of the covering humps.

11. The method for roughening silicon substrate surface in accordance with claim 1, wherein width of each of the covering bumps is between 5 and 300 μm.
